(19) United States
(12) Patent Application Publication
(10) Pub. No.: US 2014/0144371 A1
(43) Pub. Date: May 29, 2014

(54) Heat Shield For Improved Continuous Czochralski Process

(71) Applicant: SOLAICX, INC., Santa Clara, CA (US)

(72) Inventor: Tirumani N. Swaminathan, Creve Coeur, MO (US)

(73) Assignee: SOLAICX, INC., Santa Clara, CA (US)

(21) Appl. No.: 13/688,969

(22) Filed: Nov. 29, 2012

(51) Int. Cl. C30B 15/14; C30B 15/00; C30B 15/12

(52) U.S. Cl. CPC C30B 15/14; C30B 15/12; C30B 15/002
USPC 117/13; 117/213

(57) ABSTRACT

An apparatus for growing ingots by the Czochralski method is described. The ingots are drawn from a melt/crystal interface in a quantity of molten silicon replenished by crystalline feedstock. The apparatus includes a crucible configured to hold the molten silicon and a weir supported in the crucible. The weir is configured to separate the molten silicon into an inner growth region from an outer region configured to receive the crystalline feedstock. The weir includes a sidewall extending vertically and a top wall. An annular heat shield is disposed on the top wall of the weir that covers at least about 70% of the outer region.

### FIELD

The field of the disclosure relates generally to growing crystal semiconductor material by the Czochralski process. More particularly, the field of the disclosure relates to a continuous Czochralski process employing an annular heat shield for improved crystal pulling rates and crucible lifetimes.

### BACKGROUND

In a continuous Czochralski (CZ) crystal growth process, the melt is supplemented or recharged as the crystal is growing. This is in contrast with batch recharge wherein the melt is recharged after the melt is depleted by a completion of a crystal growing process. In either case the melt can be supplemented either with solid feedstock or molten feedstock.

In contrast to batch recharge, there are advantages of a continuous Czochralski process for growing crystal silicon ingots. The melt height remains substantially constant and therefore the growth conditions at the melt-crystal interface can be maintained more uniformly for optimal crystal growth. The cycle time may also be reduced because the melt conditions are not suddenly changed by the addition of a large quantity of feedstock.

A conventional weir arrangement in a conventional continuous crystal growth crucible is shown in FIG. 1. In the conventional Czochralski system, a crucible 100 holds a quantity of molten silicon 102 in which a single crystal ingot 104 is grown and pulled in a vertical direction indicated by arrow 105 from a crystal/melt interface 106. A weir 108, typically shaped as a cylinder is positioned on the floor of the crucible 100 and extends vertically above the melt as shown. The weir 108 defines an inner growth region 110 and an outer melt supplementing region 112. Subsurface passageways 114 connect the first or melt supplementing region 112 with the inner growth region 110.

A heat shield 116 is conical in shape and extends downwardly at an angle to create an annular opening disposed about the growing crystal or ingot 104 to permit the growing ingot to radiate its latent heat of solidification and thermal flux from the melt. The top of the heat shield 116 has a first diameter much wider than the diameter forming the annular opening around the ingot 104. The top of the heat shield 116 is supportably held by an insulating lid or insulation pack. The insulating lid is omitted from the drawing for the sake of simplicity. A flow of an inert gas, such as Argon, is typically provided along the length of the growing crystal as indicated at 117.

A feed supply 118 provides a quantity of silicon feedstock to the melt supplement region 112 of the crucible 100. The silicon feedstock may be in the form of solid chunks of silicon feedstock provided directly to melt region 112. In either case, addition of feedstock to the melt region is often accompanied by particles of dust transported by aerostatic forces over the top of weir 108. The dust or unmelted silicon particles contaminate the growth region 110 and can become attached to the growing ingot, thereby causing it to lose its single silicon structure.

The individual zones, growth region 110 and supplement region 112 undergo radiative and convective heat losses to the outside atmosphere. At silicon process temperatures, silicon oxide formed by dissolution of the quartz crucible evaporates from the melt and condenses on slightly cooler areas of the hot zone to form a powder or dust that may become a serious maintenance problem. When this powder or dust falls back into the silicon melt it may affect the growing single crystal structure, causing dislocation defects. Ingot yield and growth economics suffer severely. Further, the radiative and conductive heat losses require additional heat be added to keep the silicon melted. Such additional heat adds complexity and cost to the system design.

While this conventional arrangement may be adequate for limiting transmission of un-melted particles of silicon from the melt supplementing region to the crystal growth region, such conventional weir arrangements fail to address the problem of radiative and conductive heat losses to the outside atmosphere.

### BRIEF DESCRIPTION

In one aspect, an apparatus for growing ingots by the Czochralski method is disclosed. The ingots are drawn from a melt/crystal interface in a quantity of molten silicon replenished by crystalline feedstock. The apparatus includes a crucible configured to hold the molten silicon and a weir supported in the crucible configured to separate the molten silicon into an inner growth region surrounding the crystal/melt interface from an outer region configured to receive the crystalline feedstock. The weir includes at least one sidewall extending vertically and a top wall. An annular heat shield is disposed on the top wall of the weir, the annular heat shield covering at least about 70% of the outer region.

In another aspect, another apparatus for growing ingots by the Czochralski method is disclosed. The ingots are drawn from a melt/crystal interface in a quantity of molten silicon replenished by crystalline feedstock. The apparatus includes a crucible provided configured to hold the molten silicon and a feed supply for supplying the crystalline feedstock. At least two weirs are supported in the crucible, and are configured to separate the molten silicon into an inner growth region surrounding the crystal/melt interface an outer region configured to receive the crystalline feedstock and an intermediate region between the inner growth region and the outer region. The weirs each include at least one sidewall extending vertically. An annular heat shield is disposed on top of at least one of the weirs. The heat shield covers at least a portion of one of the outer region or the intermediate region.

In yet another aspect, a method for continuous Czochralski crystal growing is disclosed. In this method, one or more crystal ingots are pulled into a growth chamber from a crystal/melt interface defined in a crucible containing molten crystalline material that is replenished by crystalline feedstock. The method includes separating the molten crystalline material into an inner growth region surrounding the crystal/melt interface and an outer region for receiving the crystalline feedstock using a weir. An annular heat shield is placed over the outer region to cover at least a portion of the outer region.

### BRIEF DESCRIPTION OF THE DRAWINGS

FIG. 1 is a schematic diagram showing a conventional continuous Czochralski crystal growing system.

FIG. 2 is a schematic diagram of a continuous Czochralski system of an embodiment of the disclosure.

FIGS. 3 and 4 show top and side views of an annular heat shield of an embodiment of the disclosure.

FIG. 5 is a schematic diagram another embodiment of a continuous Czochralski system of the disclosure.

### DETAILED DESCRIPTION

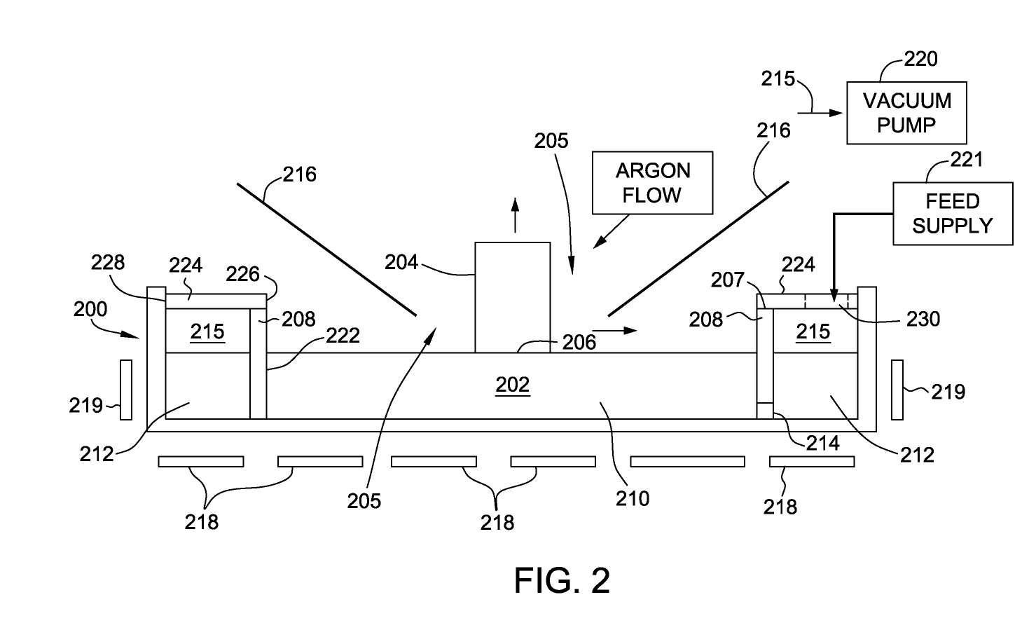

FIG. 2 shows a schematic diagram of an exemplary embodiment of an apparatus for growing ingots by the Czochralski method. In this embodiment, a weir 208 is provided in a crucible 200 that holds a silicon melt 202. The weir 208 has generally a cylindrical shape with sidewalls 222 supported at the bottom of the crucible that extend upwardly to define the growth region 210 in silicon melt 202. The weir 208 divides the melt into two portions, an inner growth region 210 and an outer, feed supplement region 212. That is, the cylindrical weir separates the growth region 210 from a first region or melt supplement region 212 to substantially isolate and prevent thermal and mechanical perturbations from affecting the growing crystal in the growth region 210. The weir 208 also defines a passageway 214 for providing a controlled melt flow between the melt supplement region 212 and growth region 210. A feed supply 221 supplies a source of solid silicon feedstock, such as chunk or granular polysilicon, to melt supplement region 212.

The crucible 200 containing the weir is disposed in a growth chamber of a Czochralski growth system. A conical heat shield 216 may be provided that depends downwardly at an angle to create an annular opening 205 disposed about the growing crystal or ingot 204 to provide protection for the crystal/melt interface 206 and the ingot 204 from extreme thermal perturbations. The top of the conical heat shield 216 has a first diameter much wider than the diameter forming the annular opening 205 around the ingot 204. The top of the conical heat shield 216 is supportably held by an insulating lid or insulation pack (not shown). The sidewalls of the conical heat shield 216 depend downwardly from the base and at an angle such that a smaller diameter distal end of the heat shield defines a central annular opening 205, large enough to receive the growing ingot, as the single crystal ingot 204 is pulled vertically as shown. The heat shield 216 can be made from molybdenum or graphite with optional silicon carbide or similar coating.

The weir 208 comprises a generally cylindrical shaped body supported on the base of the crucible 200. An annular heat shield 224 is provided at a top wall 207 of weir 208. As shown, the annular heat shield 224 is substantially perpendicular to sidewalls 222 of weir 208, and is substantially parallel to the plane of the crystal/melt interface 206. The annular heat shield 224 is defined by an inner portion 226 and an outer portion 228, such that the annular heat shield 224 substantially covers the outer region 212 such that it rests on the top wall 207 of weir 208. In one embodiment, annular heat shield 224 covers from 70% to 90% of the outer region 212.

In some embodiments, a seal is disposed between the weir 208 and annular heat shield 224 to substantially seal the annular heat shield 224 to weir 208. The seal is suitably a sealing agent including one or more layers.

The sides of the weir 208 extend substantially vertically upward, and in conjunction with annular heat shield 224, form and define an annular gap 215 with the melt 202, to allow a quantity of melt gas or purge gas to flow therethrough. The annular gap 215 may be sized appropriately to limit or control the amount of gas flow therethrough. For example, the dimensions of the annular space or gap 215 may be chosen to provide an enhanced flow path for the outflow of the argon purge gas.

The annular heat shield 224 is fabricated from silica or other suitable temperature resistant materials. The annular heat shield 224 substantially prevents radiative heat losses by containing heat within annular space 215, and preventing an outflow of heat therefrom. It will be appreciated that the materials and thickness 400 (FIG. 4) of the annular heat shield 224 may be varied to provide more or less heat shielding capability. In one embodiment, a heat reflective layer is provided on an upper or lower surface of annular heat shield 224, for example to reflect heat back into melt 202 or away from melt 202, depending on the application.

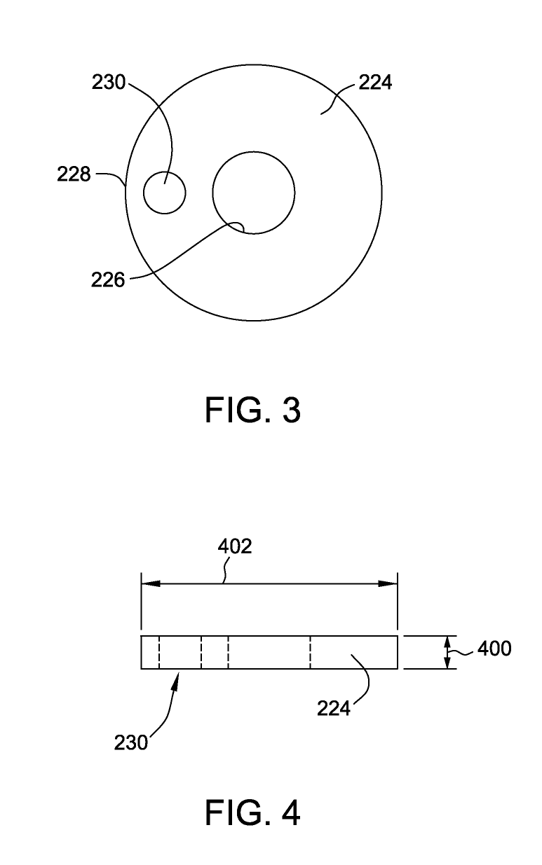

In one embodiment, annular heat shield 224 includes one or more openings 230, best shown in FIG. 3, for passing feedstock therethrough. Openings 230 are sized such that feedstock can adequately pass therethrough, without providing too large of an opening that allows a substantial amount of heat to pass through the opening.

The inner diameter of the weir 208 is chosen so as to provide sufficient melt volume in the melt region 212 such that the latent heat of fusion and thermal energy necessary to heat the solid feedstock to the melting temperature silicon 1412° C. does not cause freezing of the melt in the melt region. A plurality of collectively or independently controlled bottom heaters 218 are disposed beneath the base of the crucible 200. In another embodiment, side heaters 219 are included to provide additional controlled temperature distribution through melt 212.

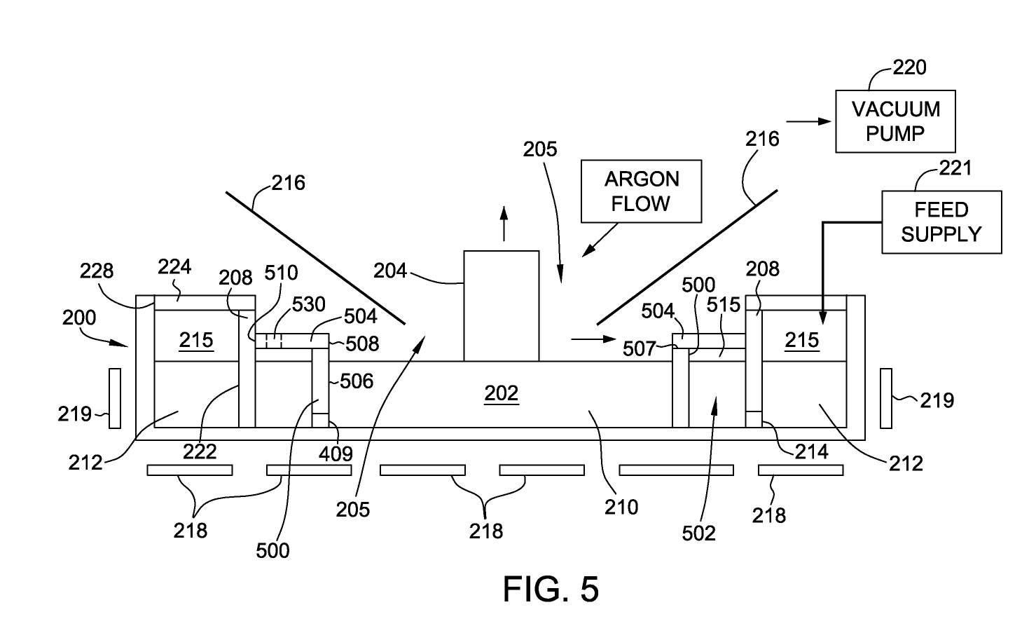

Referring now to FIG. 5, an embodiment of the continuous CZ system includes a second weir 500. In the exemplary embodiment, second weir 500 defines an interconnecting region 502 between the outer region 212 and the growth region 202. Second weir 500 may be located radially inward or radially outward from weir 208. Feedstock added from feed supply 221 to the outer region 212 of the crucible should be fully molten before it arrives in the growth region 210. Small particles in the growth region 210, particularly oxides of unmelted silicon feedstock can attach themselves to the growing ingot and cause dislocations. In addition, the melt in the growth region 210 should be devoid of large local temperature fluctuations that can cause dislocations in the growing crystal 204. Thus, additional time for feedstock to be melted is provided by the feedstock passing through the feed supplement region 212, through passageway 214, and the interconnecting region 502. Additionally, second weir 500 may define a second passageway 409 to provide a controlled melt flow between the interconnecting region 502 and growth region 210. As such, the melt in the growth region 210 can be made devoid of large local temperature fluctuations that can cause dislocations in the growing crystal 404. In this embodiment, the second weir 500 is chosen to be a height lower than weir 208, however second weir 500 may be the same height or taller than weir 208 in other embodiments.

In the exemplary embodiment, a second annular heat shield 504 is provided at a top wall 507 of second weir 500. As shown, the second annular heat shield 504 is substantially perpendicular to sidewalls 222 of weir 208 and sidewalls 506 of second weir 500, and as such, the second annular heat shield 504 is substantially parallel to the plane of the crystal/melt interface 206. The second annular heat shield 504 is defined by an inner portion 508 and an outer portion 510, such that the second annular heat shield 504 substantially covers the interconnecting region 502, and bears directly against the top wall 507 of second weir 500 and a sidewall 222 of weir 208. In another embodiment, one or more layers of a sealing agent is placed between the second weir 500 and second annular heat shield 504 to substantially seal the second annular heat shield to second weir 508. A layer of sealing agent may also be included at the interface between second annular heat shield 504 and sidewalls 222 of weir 208 for sealing purposes. The sides of the second weir 500 extend substantially vertically upward, and in conjunction with second annular heat shield 504, form and define a second annular gap 515 with the melt 202, to allow a quantity of melt gas or purge gas to flow therethrough. It will be appreciated that the second annular gap 515 between may be sized appropriately to limit or control the amount of gas flow therethrough. For example, the dimensions of the annular space or gap 515 are may be chosen to provide an enhanced flow path for the outflow of the argon purge gas.

The second annular heat shield 504 is fabricated from silica or other known temperature resistant materials. The second annular heat shield 504 substantially prevents radiative heat losses by containing heat within annular space 515, and preventing an outflow of heat therefrom. It will be appreciated that the materials and thickness of the second annular heat shield 504 may be varied to provide more or less heat shielding capability (e.g., in a manner similar to that discussed above regarding annular heat shield 224). In one embodiment, a heat reflective layer is provided on an upper or lower surface of second annular heat shield 504, for example to reflect heat back into melt 202 or away from melt 202, depending on the application.

In one embodiment, second annular heat shield 504 includes one or more openings 530 for passing feedstock, or other materials therethrough. Openings 530 are sized such that feedstock, or other materials can adequately pass therethrough, without providing too large of an opening that allows a substantial amount of heat to pass through the opening.

Exemplary embodiments of the apparatus, systems and methods for improved crystal growth in a continuous Czochralski process are described above in detail. The apparatus, systems and methods are not limited to the specific embodiments described herein, but rather, components of the systems and apparatus, and/or steps of the methods may be utilized independently and separately from other components and/or steps described herein. For example, the methods may also be used in combination with other crystal forming systems, methods, and apparatuses, and are not limited to practice with only the systems, methods, and apparatus as described herein. Rather, the exemplary embodiment can be implemented and utilized in connection with many other applications.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

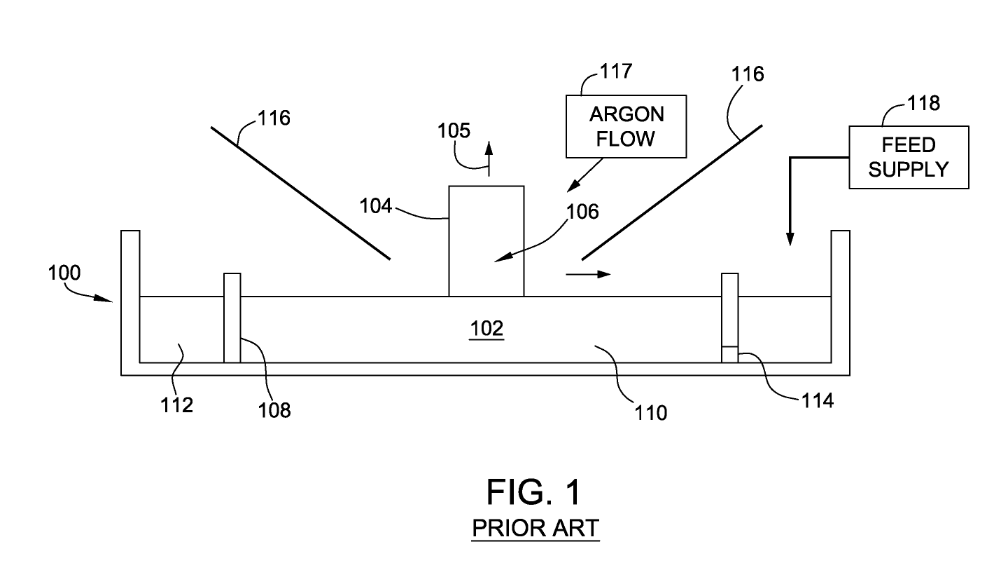

Table 1 below shows exemplary performance results of the continuous CZ system of FIG. 5 in comparison to a Comparative system with no annular heat shield, such as the system of FIG. 1.

| | Original design | With heat shield |
|---|---|---|
| Oxygen (ppma) | 11.7 | 11.6 |
| G (K/cm) | 49.5 | 48.6 |
| Heater power (kW) | 67 | 67 |
| Interface height (cm) | 10.1 | 9.15 |
| Feed zone minimum T | 1699 | 1701 |
| (K) | | |

As shown in Table 1, in a CZ process with equivalent parameters, the exemplary annular heat shields may provide a reduced interface height and a reduced parameter G. As used herein, the value of G is a measure of the axial temperature gradient in a crystal at the melt-crystal interface. As is known to one of skill in the art, G is a measure of how fast heat may be removed through the crystal and/or how quickly the crystal is cooled. For example, for a given crystal cooling configuration, a lower value of G may indicate that there is additional room for increasing the pull rate of the crystal. For a given configuration, an interface height is a measure of the vertical distance between the melt line and the topmost part of the melt-crystal interface, and may be used as a direct measure of how hot the crystal is. In some instances, a deeper interface may indicate that there is less room for increasing the crystal pull rate, due to a higher crystal temperature.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. An apparatus for growing ingots by the Czochralski method, the ingots being drawn from a melt/crystal interface in a quantity of molten silicon replenished by crystalline feedstock, the apparatus comprising:
a crucible configured to hold the molten silicon;
a weir supported in the crucible, and configured to separate the molten silicon into an inner growth region surrounding the crystal/melt interface from an outer region configured to receive the crystalline feedstock, the weir comprising at least one sidewall extending vertically and a top wall; and
an annular heat shield disposed on the top wall of the weir, the annular heat shield covering at least about 70% of the outer region.

2. The apparatus of claim 1 wherein the annular heat shield covers at least 90% of the outer region.

3. The apparatus of claim 1, wherein the annular heat shield is fabricated from silica.

4. The apparatus of claim 1, wherein the heat shield is substantially planar.

5. The apparatus of claim 1, wherein the heat shield has a cylindrical shape.

6. The apparatus of claim 1, wherein the heat shield includes an opening for passing feedstock therethrough.

7. The apparatus of claim 1, wherein the heat shield extends substantially perpendicular to the sidewall of the weir.

8. An apparatus for growing ingots by the Czochralski method, the ingots being drawn from a melt/crystal interface in a quantity of molten silicon replenished by crystalline feedstock, the apparatus comprising:
a crucible provided configured to hold the molten silicon;
a feed supply for supplying the crystalline feedstock;
at least two weirs supported in the crucible, and configured to separate the molten silicon into an inner growth region surrounding the crystal/melt interface an outer region configured to receive the crystalline feedstock and an intermediate region between the inner growth region and the outer region, the weirs each comprising at least one sidewall extending vertically;
an annular heat shield disposed on top of at least one of the weirs, the at least one heat shield covering at least a portion of one of the outer region or the intermediate region.

9. The system of claim 8, including at least two heat shields, one of the heat shields covering at least a portion of the intermediate region and the other of the heat shields covering at least a portion of the outer region.

10. The system of claim 9, wherein the heat shield covering the outer region includes one or more openings for passing the feedstock therethrough.

11. The system of claim 8, wherein the at least two weirs are substantially planar.

12. The system of claim 11, wherein the at least two weirs extent substantially perpendicularly to the sidewalls of the weirs.

13. The system of claim 8, wherein the heat shields are fabricated from silica.

14. A method for continuous Czochralski crystal growing wherein one or more crystal ingots are pulled into a growth chamber from a crystal/melt interface defined in a crucible containing molten crystalline material that is replenished by crystalline feedstock, the method comprising:
separating the molten crystalline material into an inner growth region surrounding the crystal/melt interface and an outer region for receiving the crystalline feedstock using a weir;
placing an annular heat shield over the outer region to cover at least a portion of the outer region.

15. The method of claim 14, further comprising placing a second weir in the crucible to define an intermediate region between the inner growth region and the outer region.

16. The method of claim 14, further comprising placing the annular heat shield over the outer region such that the heat shield is perpendicular to the weir.

17. The method of claim 14, further comprising passing feedstock through an opening defined in the heat shield to replenish the molten silicon.

18. The method of claim 14, further comprising placing a second weir in the crucible to define an intermediate region between the inner growth region and the outer region; and
placing at least two heat shields such that one of the heat shields covers the intermediate region and the other of the heat shields covers the outer region.
